(19) United States
(12) Patent Application Publication
(10) Pub. No.: US 2026/0293658 A1
(43) Pub. Date: Sep. 24, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Ming-Chou CHIANG, Hsinchu (TW); Hung-Yi HUANG, Hsinchu (TW); Chih-Yi CHANG, New Taipei City (TW); Ming-Hsing TSAI, Chu-Pei (TW); Chun-Chieh LIN, Taichung (TW)

(73) Assignee: Taiwan Semiconductor Manufacturing Company, Ltd., Hsinchu (TW)

(21) Appl. No.: 19/344,742

(22) Filed: Sep. 30, 2025

Related U.S. Application Data
(60) Provisional application No. 63/775,168, filed on Mar. 20, 2025.

(51) Int. Cl. H01L 21/768; H01L 23/522; H01L 23/532

(52) U.S. Cl. CPC H10W 20/46; H10W 20/056; H10W 20/072; H10W 20/076; H10W 20/42; H10W 20/4432; H10W 20/48

(57) ABSTRACT

A method includes forming at least one semiconductor component in a semiconductor device component region over a substrate. An interconnect structure including at least one contact disposed in an insulating layer is formed over the semiconductor device component region. A conductive layer is formed over the interconnect structure. The conductive layer is annealed. The annealed conductive layer is etched to form a trench in the conductive layer. A remaining portion of the conductive layer overlaps the contact in the interconnect structure. A dielectric layer is formed in the trench.

### RELATED APPLICATION

This application claims priority to U.S. Provisional Application No. 63/775,168 filed Mar. 20, 2025, the entire disclosure of which is incorporated herein by reference.

### BACKGROUND

As consumer devices with ever better performance have gotten smaller and smaller in response to consumer demand, the individual components of these devices have necessarily decreased in size as well. Semiconductor devices, which make up major components of consumer devices such as mobile phones, computer tablets, and the like, have become smaller and smaller. The decrease in size of semiconductor devices has been met with advancements in semiconductor manufacturing techniques such as forming connections between semiconductor devices. As device size decreases, resistance in smaller connections increases along with a corresponding increase in heating of the device circuitry. Lower resistance connections are desirable in smaller devices. Lower resistance means less energy is lost as heat when electricity flows through the circuitry, resulting in more efficient operation.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B show a process stage of manufacturing a semiconductor device according to embodiments of the disclosure. FIG. 1C shows a semiconductor device according to an embodiment of the disclosure.

FIGS. 2, 3, 4, 5, 6, 7, 8, 9, 10, 11, 12, and 13 show cross sectional views of stages of a method of manufacturing a semiconductor device according to embodiments of the disclosure.

FIG. 14 is a detailed cross sectional view of a metallization layer according to an embodiment of the present disclosure.

FIG. 15 shows a cross sectional view of a semiconductor device according to embodiments of the disclosure.

FIGS. 16, 17, 18, 19, 20, 21, 22, and 23 show cross sectional views of stages of a method of manufacturing a semiconductor device according to embodiments of the disclosure.

FIG. 24 is a table displaying properties of semiconductor devices according to embodiments of the disclosure.

FIG. 25 shows a flow chart for a method according to embodiments of the present disclosure.

FIG. 26 shows a flow chart for a method of manufacturing a semiconductor device according to embodiments of the present disclosure.

FIG. 27 shows a flow chart for a method of manufacturing a semiconductor device according to embodiments of the present disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C” (A, B, C, A and B, A and C, B and C, or A, B and C), and does not mean one element from A, one element from B and one element from C, unless otherwise described. In the entire disclosure, a source and a drain are interchangeably used, and a source/drain refers to one of or both of the source and the drain. Source/drain structure(s) may refer to a source or a drain, individually or collectively dependent upon the context. In the following embodiments, materials, configurations, dimensions, processes and/or operations as described with respect to one embodiment (e.g., one or more figures) may be employed in the other embodiments, and detailed description thereof may be omitted.

Disclosed embodiments relate to a semiconductor device, in particular, to a semiconductor device having low resistance and low capacitance conductive lines or wirings, and their manufacturing methods.

As semiconductor devices are scaled down in size, the space for the electrical connections between the front end of the line (FEOL) devices and back end of the line (BEOL) wiring layers becomes smaller, which increases the contact resistance of the electrical connections. In embodiments of the disclosure, a low resistance connection is provided that does not suffer from an increase in current leakage. Thus, semiconductor devices that can operate at higher power with increased efficiency are provided by embodiments of the present disclosure.

Embodiments of this disclosure relate to a metal reactive ion etching (RIE) process which achieves lower bulk resistance in some embodiments than Cu damascene process. Lower resistance means less energy is lost as heat when electricity flows through the conductive layer, such as a wire, resulting in more efficient operation. To obtain lower resistance, a thermal anneal of a conductive layer is performed before the RIE process. The thermal anneal causes the atoms in the conductive layer to rearrange themselves into a more ordered configuration, that is, grain growth occurs. This reduces the scattering of electrons in the conductive layer, which in turn reduces the resistance of the conductive layer.

The resistance is further reduced in some embodiments of the disclosure because the novel thermal annealing operation enables the use of metals like ruthenium instead of copper for wiring layers. Because copper is not used in some wiring layers, a barrier layer is not needed to prevent diffusion of copper. Thus, lower resistance barrier-less contacts can be made between wiring layers and contacts. In addition, the use of air gaps between conductive lines or wirings provides lower capacitance between the conductive lines or wirings.

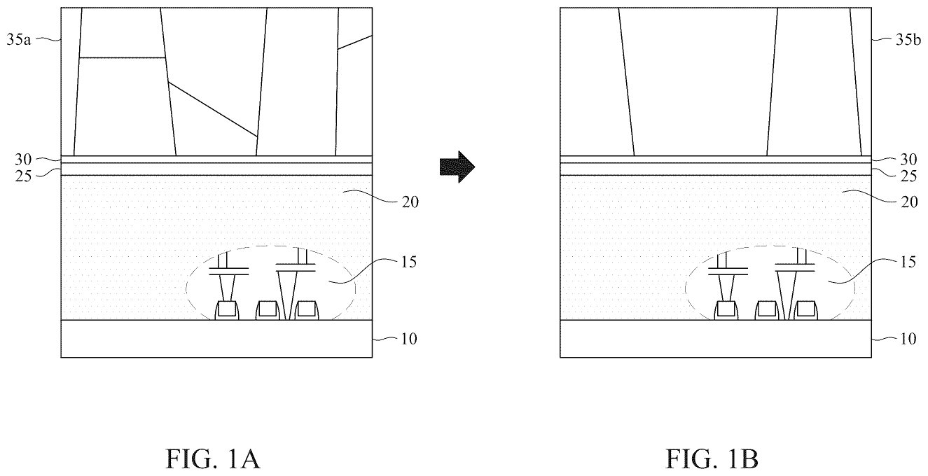

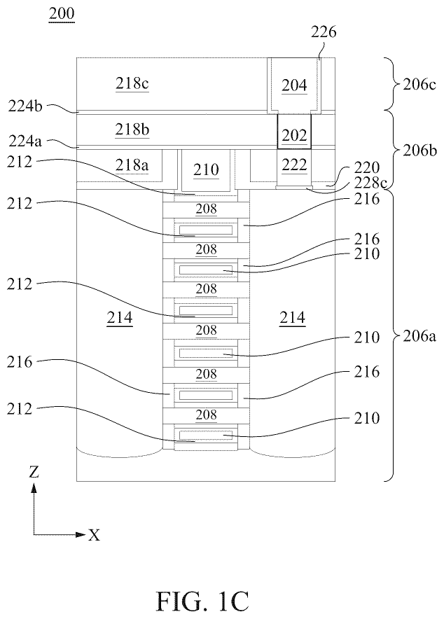

Thermal annealing according embodiments of the disclosure is shown in FIGS. 1A and 1B. A semiconductor device structure is illustrated in FIGS. 1A and 1B. The structure includes a conductive layer 35a, such as a metal layer, formed over one or more semiconductor devices or integrated circuit components 15, such as transistors, in a device region 20. As shown in FIG. 1A, the as-deposited second conductive layer 35a has randomly oriented grains, which causes grain boundary electron scattering effects. The structure is subjected to a thermal anneal, which causes grains of the conductive layer 35b to grow and become more regularly oriented in some embodiments, as shown in FIG. 1B.

In some embodiments, the average grain size of the conductive layer 35b is determined from a transmission electron microscopy (TEM) image. For example, a line of a certain length is drawn across a plan view TEM image of the conductive layer, and the number of grains that is crossed by the line is counted. The number of grains counted divided by the length of the line provides the average grain size. To obtain greater precision in the measurement of the average grain size, a plurality of lines of the same length are drawn across the face of the image and the average grain size is determined for each line. Then, the average value of the combined averages is determined. In another embodiment, the average grain size is determined in a similar manner as described above, but a cross-section TEM image of the conductive layer 35b is used instead of the plan view image.

In some embodiments, before annealing, the shortest straight-line length of a grain in the conductive layer may be less than the thickness of the conductive layer before annealing. On the other hand, after annealing, the shortest straight-line length of the grain may be greater than or equal to the thickness of the metal layer, because after annealing, the short grains disappear, leaving only the long grains extending from the top surface to the bottom surface of the metal layer. In some embodiments, the annealed conductive layer 35b has grains that have a thickness equal to the thickness of the conductive layer 35b.

The semiconductor device components 15 include semiconductor devices, including transistors, resistors, capacitors, diodes, and interconnect structures. The interconnect structures include a plurality of interconnect pattern (line) layers having conductive patterns and interconnecting various features in one portion of the die to other features of the die. The interconnect structures are formed of conductive materials such as metal and the semiconductor devices include several interconnect layers in various embodiments. The interconnect layers are often referred to as “metal 0” or “M0” (designating the lowermost interconnect level), “M1,” “M2,” and so on. These designations are used in the art to indicate that the conductive lines interconnect features from various locations in the semiconductor device. In some embodiments, the metal interconnect lines connect an array of transistors to other arrays or other features.

The interconnect layer patterns in different layers are also coupled to one another through vias that extend vertically between one or several interconnect layers. The interconnect layer patterns are coupled to external features and can represent bit lines, signal lines, word lines, and various input/output connections in some embodiments.

Examples of devices that can benefit from one or more embodiments of the present disclosure are semiconductor devices. Such a device, for example, may include static random access memory (SRAM) and/or other logic circuits, passive components such as resistors, capacitors, and inductors, and active components such as P-channel field effect transistors (PFET), N-channel FET (NFET), metal-oxide semiconductor field effect transistors (MOSFET), complementary metal-oxide semiconductor (CMOS) transistors, such as a fin field effect transistors (FinFET) and gate-all-around field effect transistors (GAA FET), complementary field effect transistors (CFET), bipolar transistors, high voltage transistors, high frequency transistors, other memory cells, and combinations thereof. The semiconductor device may include a plurality of semiconductor devices (e.g., transistors), which may be interconnected. In some embodiments, the semiconductor device components are electrically coupled through underlying interconnection layers including wiring layers and vias formed in dielectric layers, such as an interlayer dielectric (ILD) layer or an intermetal dielectric (IMD) layer. The wiring layers and vias of the interconnection layer may be formed of copper or copper alloys (e.g., AlCu), aluminum, tungsten, nickel, or any other suitable metal. It is understood, however, that the application should not be limited to a particular type of device, except as specifically claimed.

In some embodiments, the substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb, and InP. The substrate 10 may include various regions that have been suitably doped with impurities (e.g., p-type or n-type conductivity). The dopants are, for example, boron difluoride (BF₂) for an n-type Fin FET and phosphorus for a p-type Fin FET in some embodiments. In certain embodiments, the substrate 10 is made of crystalline Si.

The substrate 10 may include in its surface region, one or more buffer layers (not shown). The buffer layers can serve to gradually change the lattice constant from that of the substrate to that of the source/drain structures. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In a particular embodiment, the substrate 10 includes silicon germanium (SiGe) buffer layers epitaxially grown on the silicon substrate 10. The germanium concentration of the SiGe buffer layers may increase from 30 atomic % germanium for the bottom-most buffer layer to 70 atomic % germanium for the top-most buffer layer.

FIG. 1C illustrates a cross-sectional view of an example of a semiconductor device 15 that may be in the semiconductor device component region 20 of FIGS. 1A and 1B. FIG. 1C illustrates a transistor. In this example, the transistor is a gate-all-around field effect transistor (GAA FET), but the semiconductor devices 15 of this disclosure are not limited to transistors or GAA FETs. In addition to the transistor 15 shown in FIG. 1C, the structure 200 also includes a first device portion 206a that is formed in a series of front-end-of-line (FEOL) processes, a second device portion 206b that is formed in a series of middle-end-of-line (MEOL) processes, and a third device portion 206c that is formed in a series of back-end-of-line (BEOL) processes.

The first device portion 206a is configured as a GAA FET, and includes a plurality of semiconductor layers stacked along a thickness direction (i.e., the z-direction) and configured as stacked channel regions 208. Although six stacked channel regions 208 are shown in FIG. 1C, this disclosure is not so limited and various other embodiments include different numbers of channel regions such that the number of channel regions 208 is ≥1. This embodiment, including a GAA FET, is provided merely as an example, and various other semiconductor devices (e.g., planar field effect transistors (FETs), fin field effect transistors (FinFETs), complementary field-effect transistors (CFETs), and the like) are provided in other embodiments.

The first device portion 206a further includes a gate structure 210 surrounding each of the stacked channel regions 208. The gate structure 210 includes an electrically conductive material that is separated from the stacked channel regions 208 by a gate dielectric layer 212. The first device portion 206a further includes source/drain epitaxial layers 214 formed on opposite ends of the stacked channel regions 208 along a width direction (i.e., the x-direction) and a plurality of dielectric spacers 216 that electrically separate the gate structure 210 from the source/drain epitaxial layers 214. According to certain embodiments, a dielectric constant k of the gate dielectric layer 212 is greater than a dielectric constant of the gate spacer 216. A first interlayer dielectric (ILD) layer 218a is formed over the source/drain epitaxial layers 214, and a contact etch stop layer 220 is formed between the source/drain epitaxial layers 214 and the first ILD layer 218a. A contact plug 222 is formed in the first ILD layer 218a. The contact plug 222 penetrates through the contact etch stop layer 220 and forms an electrically conducting contact with the source/drain epitaxial layers 214. A contact via 202 forms an electrically conducting contact with the contact plug 222 and with the metal line 204. In some embodiments, the contact via 202 corresponds to the via contact 40 described in other embodiments herein. In some embodiments, the metal line 204 corresponds to the wiring layers 115, 150 described in other embodiments herein. The arrangement of the second device portion 206b and third device portion 206c schematically illustrates the electrical connection between the semiconductor devices 15 and the various components and layers of the structures described in other the embodiments described herein and the schematic illustration in FIG. 1C does not limit the arrangement of the electrical connections disclosed herein.

The first contact via 202 is formed within a second ILD layer 218b that is formed over the first ILD layer 218a in some embodiments. A first etch stop layer 224a is formed between the first ILD layer 218a and the second ILD layer 218b in some embodiments. The metal line 204 is formed in a third ILD layer 218c that is formed over the second ILD layer 218b, and a second etch stop layer 224b is formed between the second ILD layer 218b and the third ILD layer 218c in some embodiments. The metal line 204 further includes a barrier layer 226 formed between the metallic fill material and the third ILD layer 218c and between the contact via 202 and the metal line 204 in some embodiments. In some embodiments, a silicide layer 228c is disposed between the contact plug 22 and the source/drain epitaxial layers 214.

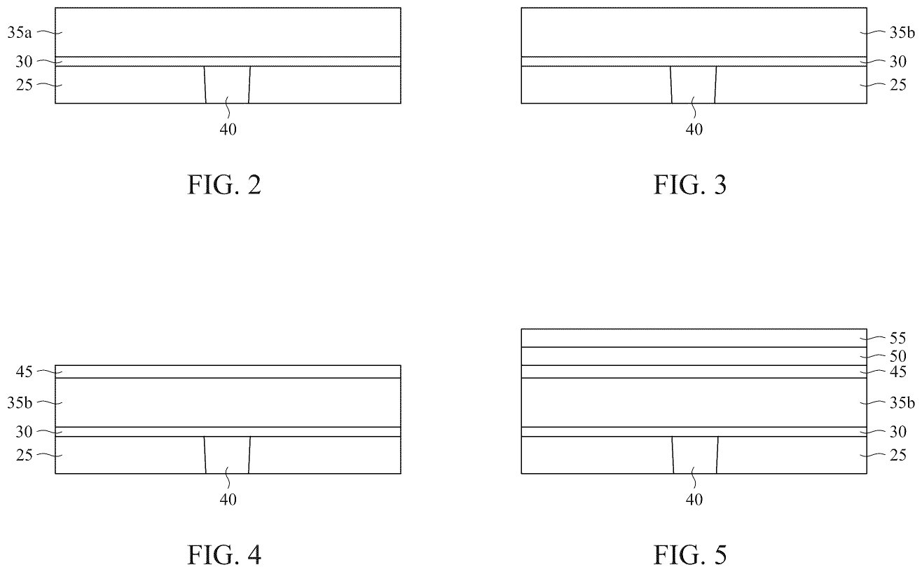

FIGS. 2 to 13 are schematic illustrations showing various stages of manufacturing a semiconductor device according to embodiments of the present disclosure. To simplify the disclosure, the semiconductor device component region 20 and the substrate are not shown in FIGS. 2 to 13. It is understood that additional operations can be provided before, during, and after processes shown by FIGS. 2-13, and some of the operations described below can be replaced or eliminated, for additional embodiments of the method. The order of the operations/processes may be interchangeable.

An insulating layer 25, such as an interlayer dielectric layer, is formed over the semiconductor device component region 20, and via contact 40 is formed in the insulating layer 25. In some embodiments, the via contact 40 includes molybdenum or another suitable conductive material formed by a bottom-up deposition process, such as atomic layer deposition (ALD) and plasma enhanced atomic layer deposition (PE-ALD). In some embodiments, there is no liner layer between the via contact 40 and the conductive layer 35b. The via contact 40 is connected to the semiconductor device components 15 through interconnects or wirings. In some embodiments, a first conductive layer 30 is formed over the insulating layer 25 and the via contact 40, as shown in FIG. 2. A second conductive layer 35a is formed over the first conductive layer 30 in some embodiments. The second conductive layer 35a is thicker than the first conductive layer 30 in some embodiments. In some embodiments, the first and second conductive layers 30, 35a form the M0 metallization layer. In some embodiments, the via contact 40 is part of an interconnect structure disposed below the conductive layers 30, 35a.

The insulating material for the insulating layer 25 may include compounds comprising Si, O, C, and/or H, such as a silicon oxide, SiCOH and SiOC, a silicon nitride, silicon oxynitride (SiON), SiOCN, SiCN, fluorine-doped silicate glass (FSG), or a low-k dielectric material, formed by LPCVD (low pressure chemical vapor deposition), plasma-enhanced CVD (PECVD), physical vapor deposition (PVD), atomic layer deposition (ALD), flowable CVD, or any suitable technique. In some embodiments, the insulating layer 25 has a thickness ranging from about 10 nm to about 50 nm.

The first conductive layer 30 may be made of TiN, TaN, TaAlC, TiC, TaC, Co, Al, TiAl, HfTi, TiSi, TaSi or TiAlC, or a multilayer of two or more of these materials. The first conductive layer may be formed by ALD, PVD, CVD, e-beam evaporation, or any other suitable technique. In some embodiments, the first conductive layer has a thickness ranging from about 1 nm to about 10 nm, and from about 2 nm to about 5 nm in other embodiments.

The second conductive layer 35a may be made of ruthenium, rhodium, palladium, osmium, iridium, platinum, titanium, tantalum, tungsten, cobalt, molybdenum, or combinations or alloys thereof. The second conductive layer 35a may be formed by ALD, PVD, CVD, e-beam evaporation, electroplating, electroless plating, or any other suitable technique. In some embodiments, the second conductive layer 35a has a thickness ranging from about 10 nm to about 50 nm, and from about 20 nm to about 30 nm in other embodiments.

The second conductive layer 35a is made of a conductive material having a first average grain size. The second conductive layer 35a is subsequently treated to form a second conductive layer 35b having second average grain size larger than the first average grain size. In some embodiments, the second conductive layer 35a is subjected to a heat treatment to form the second conductive layer 35b having a larger average grain size. In an embodiment, the heat treatment includes thermally annealing the second conductive layer at a temperature ranging from about 300° C. to about 450° C. In other embodiments, the temperature of the thermal annealing ranges from about 350° C. to about 400° C. In an embodiment, the heating the conductive layer is performed in an ambient including at least one of an inert gas. In some embodiments, the heat treatment is performed in an ambient including at least one of Ar, N₂, H₂, or H radicals. In some embodiments, the heat treatment is formed in an ambient including forming gas (a mixture of argon, nitrogen, and hydrogen). The heat treatment provides an average grain size increase of up to or more than about 2 times, and a reduction of conductive layer resistance of up to or more than about 36% without any yield or reliability degradation. For example, in some embodiments where the conductive layer is subjected to a hydrogen radical anneal, the average grain size increase is greater than 150% in some embodiments, and the resistance of the conductive layer decreases by more than 30% over embodiments not subjected to the anneal processes disclosed herein. At heat treatment temperatures below the disclosed ranges there may not be sufficient grain growth. At heat treatment temperatures above the disclosed ranges the underlying semiconductor device components may be damaged.

An etch stop layer 45 is formed over the second conductive layer 35b after the heat treatment operation in some embodiments, as shown in FIG. 4. In some embodiments, the etch stop layer 45 is made of TiN or TaN. The etch stop layer may be formed by ALD, PVD, CVD, e-beam evaporation, or any other suitable technique. In some embodiments, the etch stop layer has a thickness ranging from about 5 nm to about 40 nm, and from about 10 nm to about 20 nm in other embodiments.

A hard mask layer 50, 55 is formed over the etch stop layer 45, as shown in FIG. 5. In some embodiments, the hard mask layer includes a first hard mask layer 50 and a second hard mask layer 55 made of different materials. In some embodiments, the first hard mask layer 50 is a silicon nitride and the second hard mask layer 55 is a silicon oxide. In some embodiments, the first and second hard mask layers 50, 55 are made by CVD, PVD, ALD, or any other suitable technique. In some embodiments, the first and second hard mask layers 50, 55 each have a thickness ranging from about 5 nm to about 40 nm, and a thickness ranging from about 10 to about 20 nm in other embodiments.

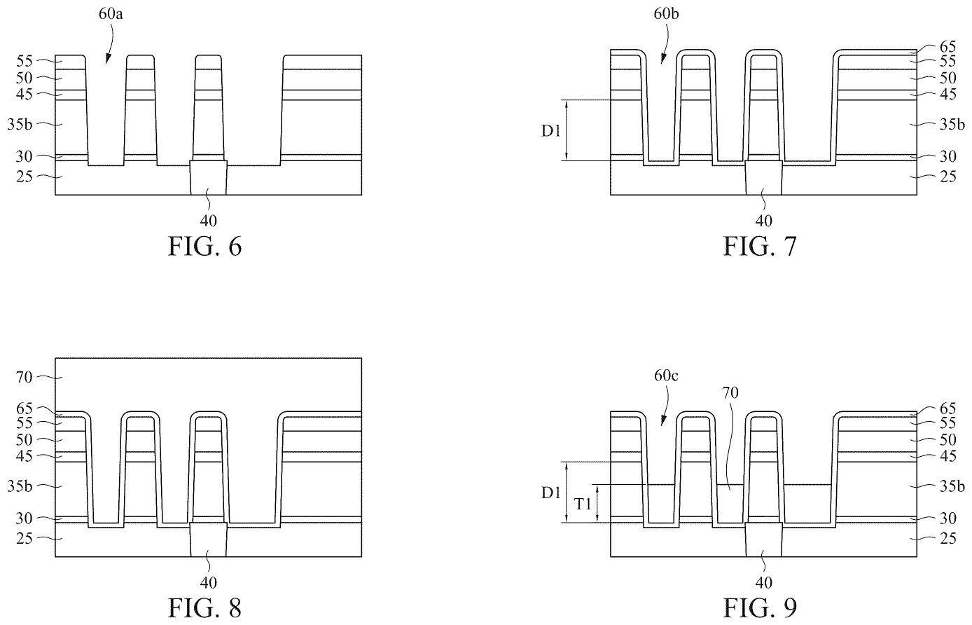

The second conductive layer 35b is patterned to form trenches 60a, as shown in FIG. 6. The patterning is performed by photolithographic and etching operations in some embodiments. In some embodiments, a photoresist layer is formed over the second hard mask layer 55. The photoresist layer is selectively exposed to actinic radiation, and then the selectively exposed photoresist layer is developed to form a pattern corresponding to the pattern of trenches to be formed. The hard mask layers 50, 55 are etched using suitable etchants using the patterned photoresist layer as a mask to form a hard mask 50, 55 exposing the etch stop layer 45. The remaining photoresist layer is subsequently removed using a suitable stripping or plasma ashing operation. The pattern in the hard mask 50, 55 is extended into the etch stop layer 45, second conductive layer 35b, and first conductive layer 30 using suitable etching operations to form trenches 60a, as shown in FIG. 6. In some embodiments, different etchant compositions are used to etch the different layers. In some embodiments, the trench 60a extends into the insulating layer 25.

In some embodiments, the trench 60a is formed using an anisotropic etching technique, such as reactive ion etching (RIE). RIE is used to etch the etch stop layer 45, the second conductive layer 35b, and the first conductive layer 30. RIE provides efficient metal removal and improved control of etching parameters of the etching of both metal layers and dielectric layers.

RIE uses reactive gases in a plasma state to chemically and physically remove the material being etched. The reactive gas used in the RIE operation may include H₂, O₂, Cl₂, F₂, BCl₃, SF₆ CH₄, CHF₃, or combinations thereof. The etching gas may include an inert gas, such as Ar or N₂. In some embodiments, the pressure in the etching chamber during the etching operation ranges from about 5 mTorr to about 400 mTorr, and between 10 mTorr to about 300 mTorr in other embodiments.

Different etching gases may be used for etching the different layers. For example, in an embodiment where the first conductive layer 30 and etch stop layer 45 are made of TiN and the second conductive layer is made of ruthenium, the TiN layers are etched using a mixture of CH₄ and O₂, while the ruthenium is etched using a mixture of Cl₂ and O₂.

A cap layer or liner layer 65 is conformally formed in the trench 60b, along the trench sidewalls, and over the hard mask 55, 50, as shown in FIG. 7. In some embodiments, the cap layer 65 is made of at least one of a silicon nitride, SiON, SiCN, an oxide doped carbide such as SiOC, SiOCN, or any other suitable dielectric material. The cap layer 65 shields the conductive layer from environmental interaction, such as water vapor infiltration. In some embodiments, the cap layer has a thickness ranging from about 0.5 nm to about 6 nm, and from about 1 nm to about 3 nm in other embodiments. The cap layer 65 can be formed by ALD or CVD, or any other suitable method.

A depth D1 of the trench 60b from an uppermost surface of the second conductive layer 35b to the upper surface of the portion of the cap layer 65 covering the insulating layer 25 at the bottom of the trench 60b ranges from about 11 nm to about 60 nm in some embodiments, and from about 22 nm to 35 nm in other embodiments.

An organic sacrificial polymer layer 70 is formed over the cap layer 65, as shown in FIG. 8. The organic polymer has a low decomposition temperature in some embodiments. In some embodiments, the organic polymer includes at least one selected from the group consisting of polyethylene, polypropylene, polymethylmethacrylate, poly(meth)acrylic acid, polyvinyl alcohol, polyvinyl acetate, and any other suitable polymer. The polymer layer 70 may be applied by spin coating. By controlling process parameters of spin-coating, the polymer layer 70 thickness in narrow and wide spaces can be differentiated corresponding to the trench and pattern feature density.

The sacrificial polymer layer is subsequently etched-back using a suitable etching technique to remove the polymer overlying the upper surfaces of the cap layer and leave portion of the sacrificial polymer layer in the trenches 60c, as shown in FIG. 9. In some embodiments, the thickness T1 of the polymer layer 70 in the trenches 60c ranges from about 0.3 nm to about 20 nm, and from about 1 nm to about 10 nm in other embodiments. In some embodiments, a ratio of the thickness T1 of the polymer layer to the depth D1 of the trench 60c from the uppermost surface of the second conductive layer 35b to the upper surface of the portion of the cap layer 65 covering the insulating layer 25 at the bottom of the trench 60b ranges from about 0.01 to about 0.67, and from about 0.03 to about 0.45 in other embodiments, and from about 0.17 to about 0.3 in yet other embodiments.

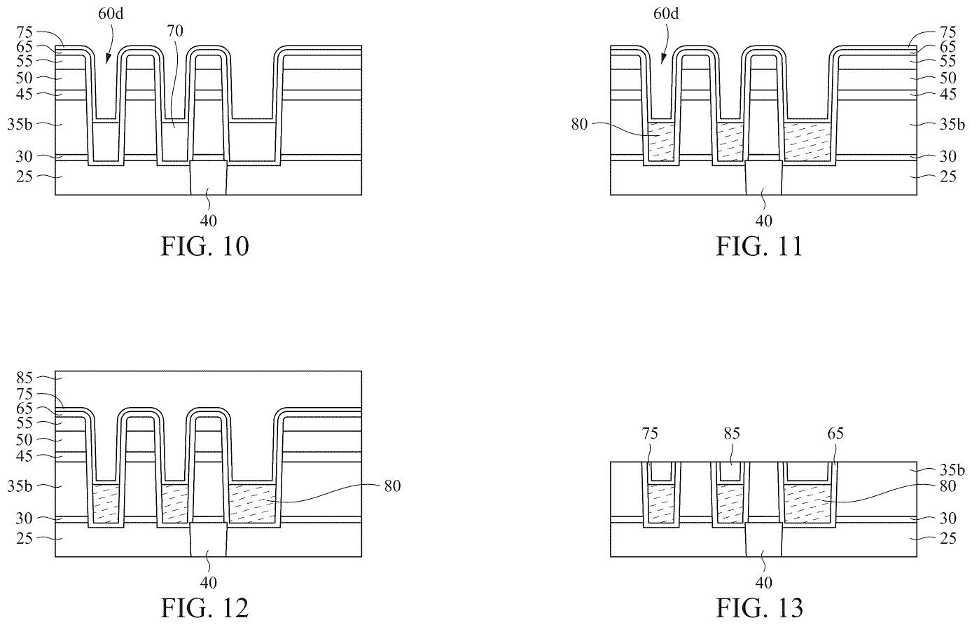

A sustain layer 75 is conformally formed in the trench 60d, along the trench sidewalls, over the polymer layer 70, and over the cap layer 65, as shown in FIG. 10. In some embodiments, the sustain layer 75 is made of at least one of a silicon nitride, SiON, SiCN, an oxide doped carbide such as SiOC, SiOCN, or any other suitable dielectric material. The sustain layer 75 shields the conductive layer from environmental interaction, such as water vapor infiltration. In some embodiments, the sustain layer 75 has thickness ranging from about 0.5 nm to about 6 nm, and from about 1 nm to about 3 nm in other embodiments. In some embodiments, the sustain layer 75 is made of a different material than the cap layer 65. In some embodiments, the sustain layer 75 has a different thickness than the cap layer 65. The sustain layer 75 can be formed by ALD or CVD, or any other suitable method.

After forming the sustain layer 75, the remaining portions of the polymer layer 70 are removed from the trenches 60d forming air gaps 80, as shown in FIG. 11. The remaining portions of the polymer layers are removed by thermal decomposition or thermal oxidation in some embodiments. In some embodiments, the structure is heated at a temperature ranging from about 100° C. to about 400° C. in an oxygen-containing ambient, an inert atmosphere, or in a vacuum. In an oxygen-containing ambient, the polymer is removed by thermal oxidation. In an inert atmosphere, the polymer layer is removed by thermal decomposition. In air, the polymer layer is removed by thermal oxidation. In some embodiments, the structure is heated at a temperature ranging from about 200° C. to about 350° C. while removing the remaining portion of the polymer layer. At temperatures below the disclosed ranges there may be insufficient removal of the polymer layer. At temperatures above the disclosed ranges underlying semiconductor device components may be damaged.

An upper dielectric layer 85 is formed over the sustain layer 75 and fills the trenches 60d, as shown in FIG. 12. In some embodiments, the upper dielectric layer 85 is made of a silicon oxide, a silicon nitride, a silicon oxynitride (SiON), SiOCN, SiCN, fluorine-doped silicate glass (FSG), or a low-k dielectric material, formed by LPCVD, PECVD, PVD, ALD, flowable CVD, or any suitable technique.

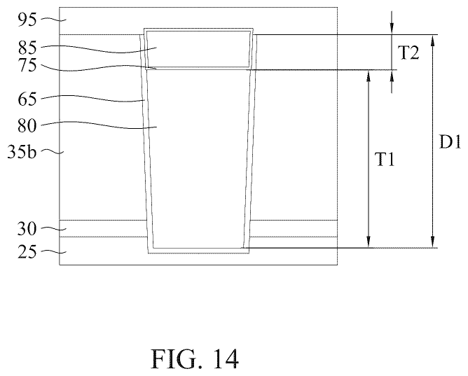

The upper dielectric material 85 overlying the pattern projections is removed, and the hard mask layers 50, 55, and the etch stop layer 45 are removed, as shown in FIG. 13, to form a patterned metallization layer. The upper dielectric material 85, hard mask layers 50, 55, and etch stop layer 45 may be removed by an anisotropic dry etch-back operation or by chemical-mechanical polishing (CMP). In some embodiments, a CMP operation is performed, and the CMP operation is stopped when the second conductive layer 35b is exposed. The CMP operation provides a planarized structure with spaced apart conductive lines or contacts. As shown in FIG. 14, a thickness T2 of the remaining portion of the upper dielectric layer 85 and the sustain layer 75 ranges from about 5 nm to about 40 nm in some embodiments, and from 10 nm to about 20 nm in other embodiments. In some embodiments, at least one of the conductive lines or contacts are electrically connected to an underlying semiconductor device component 15 through the via contact 40.

In some embodiments, an additional heat treatment is performed after the CMP operation to further increase the average grain size of the second conductive layer 35b. In some embodiments, the additional treatment includes a thermal treatment at a temperature ranging from about 300° C. to about 450° C. in an ambient including at least one of Ar, N₂, H₂, or H radicals.

FIG. 14 is a detailed cross sectional view of a metallization layer according to an embodiment of the present disclosure. In some embodiments, a second etch stop layer (not shown) or a second insulating layer 95 is formed over the structure of FIG. 13. The second insulating layer 95 may include a silicon oxide, a silicon nitride, SiON, SiOCN, SiCN, FSG, or a low-k dielectric material, formed by LPCVD, PECVD, PVD, ALD, flowable CVD, or any suitable technique. In some embodiments, the second insulating layer 95 is an interlayer dielectric layer (ILD). In some embodiments, the second insulating layer 95 has a thickness ranging from about 10 nm to about 50 nm.

In some embodiments, a ratio of the thickness T1 of the air gap 80 to the depth D1 of the remaining portion of the trench 60d from the uppermost surface of the second conductive layer 35b to the upper surface of the portion of the cap layer 65 covering the insulating layer 25 at the bottom of the trench 60d ranges from about 0.1 to about 0.8, and the ratio ranges from about 0.15 to about 0.6 in other embodiments, and the ratio ranges from about 0.2 to about 0.4 in yet other embodiments. In some embodiments, a ratio of the thickness T2 of the upper dielectric layer 55 and the sustain layer 75 to the thickness T2 of the air gap 80 ranges from about 0.2 to about 0.9, and in other embodiments the ratio ranges from about 0.3 to about 0.75, and in yet other embodiments, the ratio ranges from about 0.4 to about 0.6. At ratios of T1/D1 and T2/T1 outside the disclosed ranges, a desired capacitance between adjacent conductive lines or wirings may not be achieved.

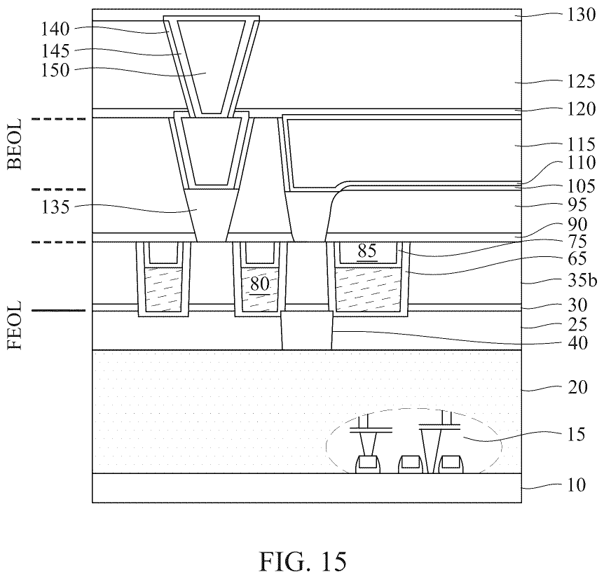

In some embodiments, additional processing is performed to produce the device shown in FIG. 15. According to embodiments of the disclosure, the additional processing includes BEOL processing, including forming additional metallization layers and additional etch stop layers 90, 120, 130 between adjacent metallization layers. The additional metallization layers include interlayer dielectric layers 95, 125, wiring layers 115, 150; and via contacts 135. In some embodiments, the via contact 135 between the wiring layer 115 and the conductive layer 35b is made of suitable conductive material, such as molybdenum. In some embodiments, the molybdenum via contact 135 is formed by a bottom-up deposition process, such as atomic layer deposition (ALD) and plasma enhanced-atomic layer deposition (PE-ALD). In some embodiments, there is no liner layer between the via contact 135 and the conductive layer interlayer dielectric layer 95. In some embodiments, the via contact 135 is in the V0 via layer.

In some embodiments, the wiring layers 115 are in the M1 interconnect layer. In some embodiments where the wiring layers are copper wiring layers, barrier layers 105, 140 are interposed between the copper wiring layers and the ILD layer to prevent copper diffusion into the ILD layer. In some embodiments, the barrier layers 105, 140 are made of a tantalum nitride. In some embodiments, liner layers 110, 145, are disposed between the barrier layer 105, 140 and the wiring layers 115, 150. In some embodiments, the liner layers are made of cobalt, ruthenium, and alloys thereof.

In some embodiments, the interconnect and via layers, are formed by depositing a dielectric layer, photolithographically etching vias and/or trenches in the dielectric layers, and depositing a barrier layer over sidewalls of the vias and contacts. The barrier layer 105, 140 may be made of a tantalum nitride and may be deposited by ALD, PVD, CVD, or any other suitable technique. In some embodiments, the barrier layer 105, 140 has a thickness ranging from about 1 nm to about 20 nm. The barrier layer may be removed over the via contact 135 to provide a barrier free contact and allow a reduced resistance contact of the via contact 135 to the wiring layer 115.

Liner layers 110, 145 may be formed over the barrier layers 105, 140 and the via contact 135. In some embodiments, the liner layers 110, 145 are made of ruthenium, cobalt, and/or alloys thereof deposited by ALD, PVD, CVD, e-beam evaporation, electroplating, electroless plating, or any other suitable technique. The liner layers 110, 145 may improve adhesion of the wiring layers 115, 145, provide a nucleation site for the wiring layer metal, provide a moisture block, and in conjunction with the barrier layers 105, 140 prevent copper diffusion into the surrounding dielectric layer 95, 125. In some embodiments, the liner layers 110, 145 have a thickness ranging from about 1 nm to about 20 nm. In some embodiments, the liner layers 110, 145 are made of ruthenium and have an average grain size of about 10 nm to about 12 nm measured in a cross section view and have a resistivity of about 20 μohm-cm to about 22 μohm-cm.

Wiring layers 115, 150 are deposited over the liner layers 110, 145 in some embodiments. The wiring layers 115, 150 may be made of copper, aluminum, alloys thereof, or any other suitable high conductivity metal. The wiring layers 115, 150 may be deposited by ALD, PVD, CVD, e-beam evaporation, electroplating, electroless plating, or any other suitable technique. In some embodiments, liner layers 110, 145 are also formed by ALD, PVD, CVD, e-beam evaporation, electroplating, electroless plating or any other suitable technique over the upper surface of the wiring layers 115, 150 before forming the etch stop layers 120, 130 over the wiring layers 115, 150 and interlayer dielectric layers 95, 125. The liner layers 110, 145 may provide a moisture block and prevent copper diffusion into the surrounding etch stop layer 120, 130 and dielectric layer 95, 125.

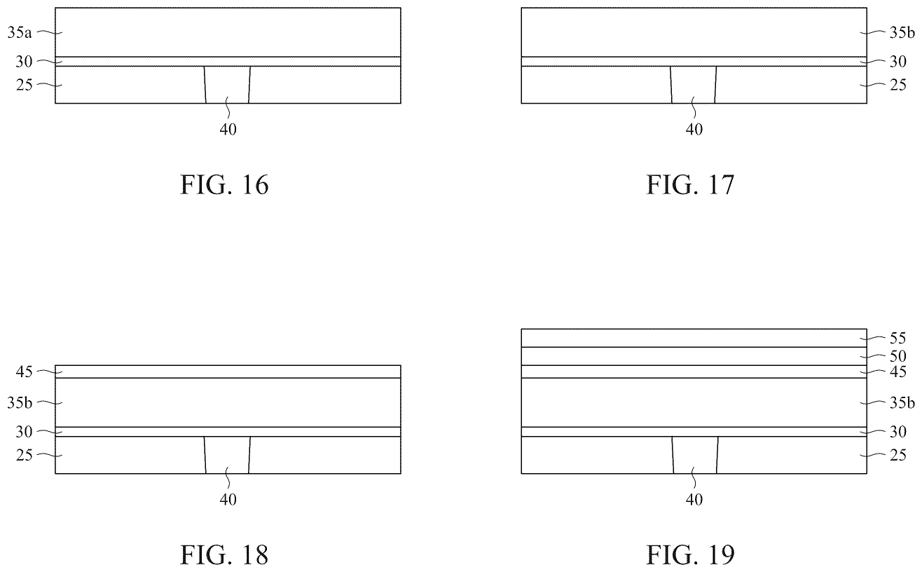

FIGS. 16-23 show cross sectional views of stages of a method of manufacturing a semiconductor device according to embodiments of the disclosure. To simplify the disclosure, the semiconductor device component region 20 and the substrate 10 are not shown in FIGS. 16 to 23. It is understood that additional operations can be provided before, during, and after processes shown by FIGS. 16 to 23, and some of the operations described below can be replaced or eliminated, for additional embodiments of the method. The order of the operations/processes may be interchangeable.

An insulating layer 25, such as an interlayer dielectric layer, a first conductive layer 30, and a second conductive layer 35a are formed over the semiconductor device component region 20, and a via contact 40 is formed in the insulating layer 25, as shown in FIG. 16. The via contact 40 is connected to the semiconductor device components 15 through interconnects or wirings. The insulating layer 25, first conductive layer 30, second conductive layer 35a, and via contact 40 are formed of the same materials and same processes as described herein in reference to FIG. 2.

The average grain size of the second conductive layer 35b in FIG. 17 is increased in the same manner as described herein in reference to FIGS. 1B and 3.

An etch stop layer 45 is formed over the second conductive layer 35b after the heat treatment operation in some embodiments, as shown in FIG. 18. The etch stop layer 45 is formed in the same manner and with the same materials as disclosed herein in reference to FIG. 4.

A hard mask layer 50, 55 is formed over the etch stop layer 45, as shown in FIG. 19. In some embodiments, the hard mask layer includes a first hard mask layer 50 and a second hard mask layer 55 made of different materials. The first and second hard mask layers 50, 55 are formed in the same manner and with the same materials as disclosed herein in reference to FIG. 5.

The second conductive layer 35b is patterned to form trenches 60a, as shown in FIG. 20. The patterning is performed by photolithographic and etching operations in some embodiments. The trenches 60 may be formed in the same manner as disclosed herein in reference to FIG. 6

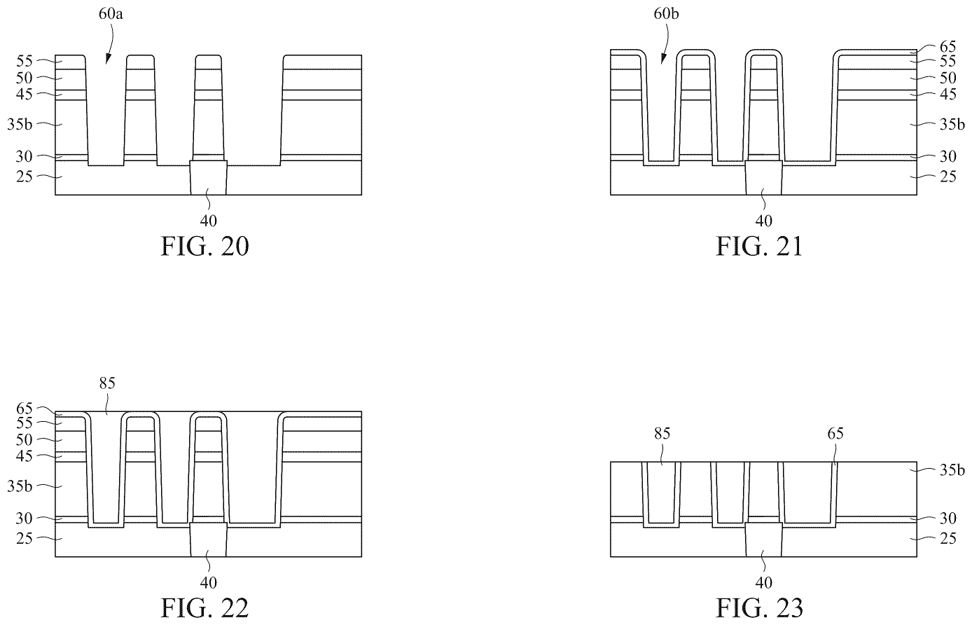

A cap layer 65 is conformally formed in the trench 60b, along the trench sidewalls, and over the hard mask 55, 50, as shown in FIG. 21. The cap layer 65 is formed in the same manner and with the same materials as disclosed herein in reference to FIG. 7.

An upper dielectric layer 85 is formed over the cap layer 65 and fills the trenches 60b, as shown in FIG. 22. The upper dielectric layer 85 is formed in the same manner and with the same materials as disclosed herein in reference to FIG. 12. In some embodiments, the upper dielectric layer 85 is made of a silicon oxide, a silicon nitride, a silicon oxynitride (SiON), SiOCN, SiCN, fluorine-doped silicate glass (FSG), or a low-k dielectric material, formed by LPCVD, PECVD, PVD, ALD, flowable CVD, or any suitable technique.

The upper dielectric material 85 overlying the pattern projections is removed, and the hard mask layers 50, 55, and the etch stop layer 45 are removed, as shown in FIG. 23, to form a patterned metallization layer. The upper dielectric material 85, hard mask layers 50, 55, and etch stop layer 45 may be removed by an anisotropic dry etch-back operation or by chemical-mechanical polishing (CMP). In some embodiments, a CMP operation is performed, and the CMP operation is stopped when the second conductive layer 35b is exposed. The CMP operation provides a planarized structure with spaced apart conductive lines or contacts. In some embodiments, at least one of the conductive lines or contacts are electrically connected to an underlying semiconductor device component 15 through the via contact 40.

In some embodiments, an additional heat treatment is performed after the CMP operation to further increase the average grain size of the second conductive layer 35b. In some embodiments, the additional treatment includes a thermal treatment at a temperature ranging from about 300° C. to about 450° C. in an ambient including at least one of Ar, N₂, H₂, or H radicals.

In some embodiments, additional BEOL processing is performed on the structure of FIG. 23, as disclosed herein in reference to FIG. 15.

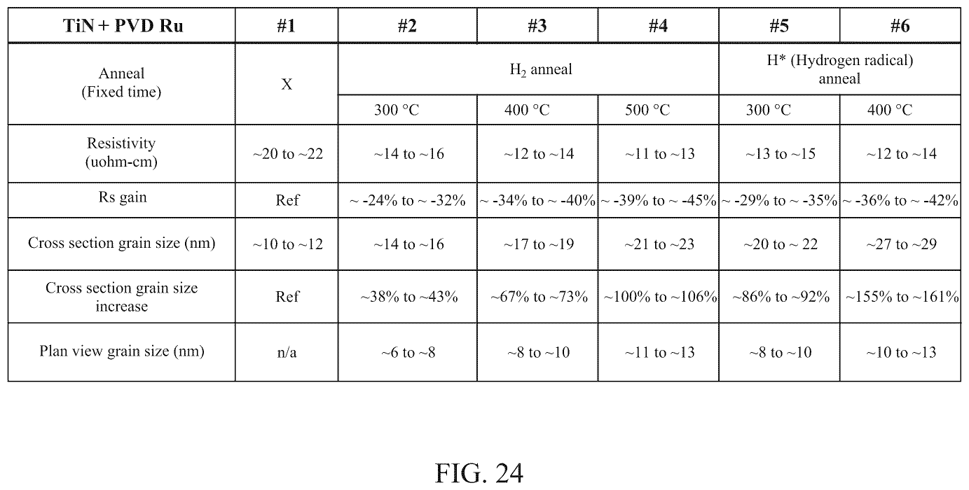

FIG. 24 is a table displaying properties of semiconductor devices according to embodiments of the disclosure. FIG. 24 shows the unexpected improvement in the conductive layer resistivity and increase in average grain sizes in semiconductor devices according to embodiments of the present disclosure. The structures in Embodiments 1-6 include a first conductive layer made of TiN and a second conductive layer made of Ru. Embodiment 1 does not include the conductive layer annealing operation disclosed herein. Embodiments 2, 3, and 4 represent annealing in an ambient including hydrogen at 300° C., 400° C., and 500° C., respectively for the same amount of time. In some embodiments, the time duration of the annealing operation ranges from about 5 min to about 30 min. Embodiments 5 and 6 represent annealing in an ambient including hydrogen radicals at 300° C. and 400° C., respectively, for the same amount of time as Embodiments 2, 3, and 4. Embodiments of the disclosure provide an unexpected decrease in resistivity of greater than about 20% to greater than about 40% of the Ru conductive layer over embodiments not subjected to the annealing operation. Furthermore, embodiments of the disclosure show an unexpected increase in the cross sectional average grain size of greater than about 40% to greater than about 150% of the Ru grains in the Ru conductive layer over the cross sectional average grain size of semiconductor devices not subjected to the annealing operation. In addition, in the Embodiments, the plan view average grain size increases with increasing annealing temperature. Furthermore, annealing in the ambient including the hydrogen radicals provides a further unexpected higher level of resistance reduction and larger average grain size increase at a same annealing temperature as the hydrogen ambient anneal.

In some embodiments, the average cross sectional grain size of the ruthenium in the conductive layer 35b after the annealing operation disclosed herein ranges from about 38% to about 161% larger than the average cross sectional grain size of the ruthenium in the conductive layer 35a before the annealing operation, from about 60% to about 120% larger in other embodiments, and from about 80% to about 100% larger in yet other embodiments. In some embodiments, the resistivity of the conductive layer 35b after the annealing operation disclosed herein ranges from about 24% to about 45% lower than the average resistivity of the conductive layer 35a before the annealing operation, and from about 30% to about 40% lower in other embodiments.

The liner layers 110, 145 surrounding the wiring layers 115, 150 do not undergo the conductive layer annealing operation disclosed herein. Thus, when the liner layers 110, 145 are made of ruthenium they have a smaller average grain size and a higher resistivity than the ruthenium grains in the conductive layer 35b. In some embodiments, the average cross sectional grain size of the ruthenium in the conductive layer 35b ranges from about 38% to about 161% larger than the average cross sectional grain size of the ruthenium in the liner layers 110, 145, from about 60% to about 120% larger in other embodiments, and from about 80% to about 100% larger in yet other embodiments. In some embodiments, the resistivity of the conductive layer 35b ranges from about 24% to about 45% lower than the average resistivity of the liner layers 110, 145, and from about 30% to about 40% lower in other embodiments.

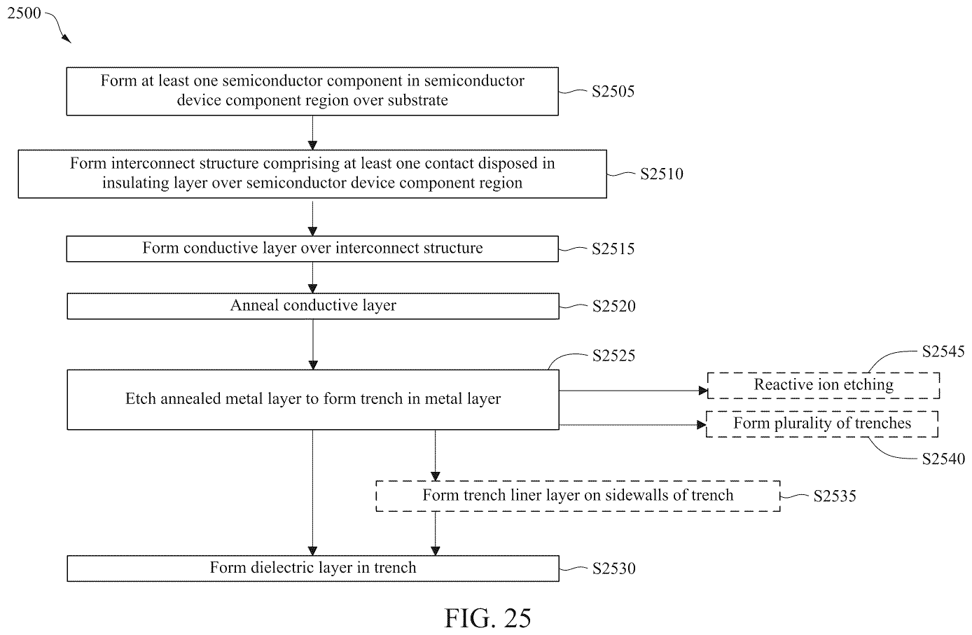

FIG. 25 shows a flow chart for a method 2500 according to embodiments of the present disclosure. The method includes an operation S2505 of forming at least one semiconductor component 15 in a semiconductor device component region 20 over a substrate 10. An interconnect structure 15 including at least one contact 40 disposed in an insulating layer 25 is formed over the semiconductor device component region 20 in operation S2510. In operation S2515, forming a conductive layer 35a is formed over the interconnect structure 15. The metal layer 35b is annealed in operation S2520, and the annealed metal layer 35b is etched in operation S2525 to form a trench 60a in the metal layer. A remaining portion of the metal layer 35b overlaps the contact 40 in the interconnect structure 15. A dielectric layer 80, 85 is formed in the trench 60d in operation S2530. In some embodiments, the method includes an operation S2535 of forming a trench liner layer 65 on sidewalls of the trench before forming the dielectric layer 80, 85. In some embodiments, the etching the annealed metal layer includes an operation S2540 of forming a plurality of trenches 60a. In some embodiments, the etching is a reactive ion etching operation S2545.

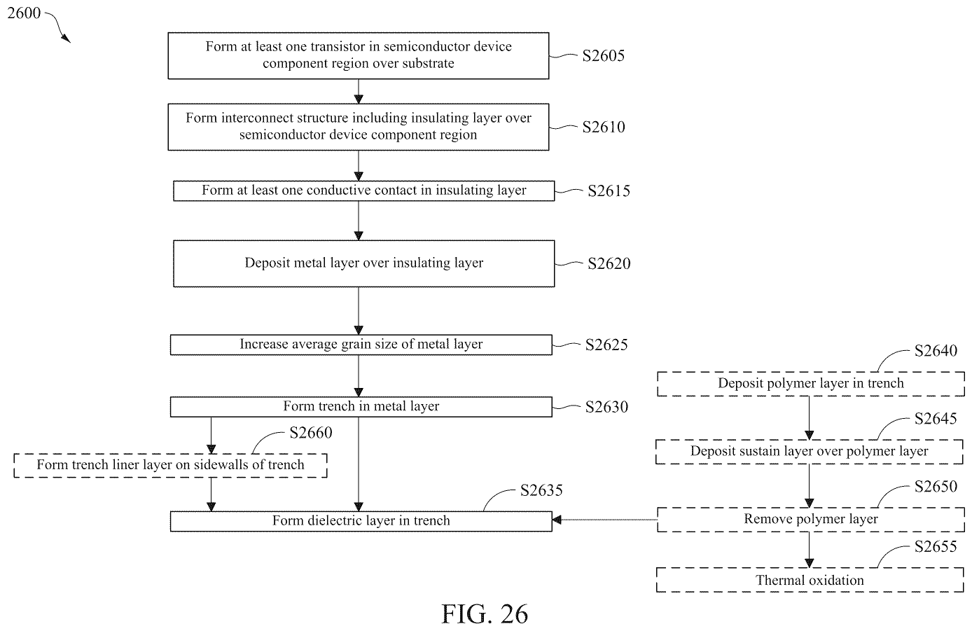

FIG. 26 shows a flow chart for a method 2600 of manufacturing a semiconductor device, including forming at least one transistor 15 in a semiconductor device component region 20 over a substrate 10 in operation S2605. In operation S2610, an interconnect structure 15 including an insulating layer 25 is formed over the semiconductor device component region 20. In operation S2615, at least one conductive contact 40 is formed in the insulating layer 25. In operation S2620, a metal layer 35a is deposited over the insulating layer 25. Then the average grain size of the metal layer 35b is increased in operation S2625. After increasing the average grain size of the metal layer 3b, a trench 60a is formed in the metal layer 35b in operation S2630. At least one remaining portion of the metal layer 35b overlaps the at least one conductive contact 40 in the insulating layer 25. A dielectric layer 80, 85 is formed in the trench 60b in operation S2635. An air gap 80 is formed in operation S2640, depositing a polymer layer 70 in the trench 60b; operation S2645, depositing a sustain layer 75 over the polymer layer 70; and operation S2650, removing the polymer layer after depositing the sustain layer. The polymer layer is removed by a thermal oxidation operation in operation S2655. In operation S2660, a trench liner layer 65 is formed on sidewalls of the trench 60b before forming the dielectric layer 80, 85.

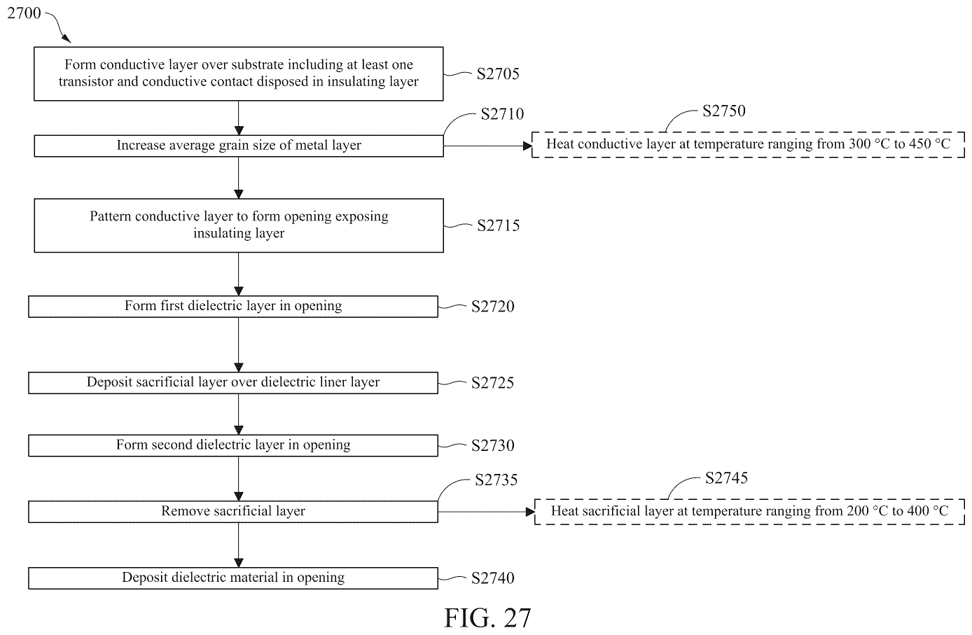

FIG. 27 shows a flow chart for a method 2700 of manufacturing a semiconductor device, including forming a conductive layer 35a over a substrate 10 including at least one transistor 15 disposed and a conductive contact 40 connected to the at least one transistor 15 disposed in an insulating layer 25 in operation S2705. The at least one transistor includes a gate structure including a gate electrode 210 and a gate dielectric layer 212 having a first dielectric constant k1. An average grain size of the conductive layer 35b is increased in operation S2710. After increasing the average grain size of the conductive layer, the conductive layer is patterned in operation S2715 to form an opening 60a exposing the insulating layer 25. At least one remaining portion of the conductive layer 35b overlaps a conductive contact 40 in the insulating layer 25. In operation S2720, a first dielectric liner layer 65 is formed in the opening 60b. A sacrificial layer 70 is formed over the dielectric liner layer 65 in operation S2725. In operation S2730, a second dielectric layer 75 is formed in the opening 60d. Then, the sacrificial layer 70 is removed in operation S2735 to form a gap having a second dielectric constant k2, and a dielectric material 85 having a third dielectric constant k3 is deposited in the trench 60d in operation S2740. The third dielectric material is made of a different material than the second dielectric layer, k2 and k3 are different, k1>k2, and k1>k3. In some embodiments, removing the sacrificial layer includes heating the sacrificial layer at a temperature ranging from 200° C. to 400° C. in operation S2745. In some embodiments, the increasing the average grain size of the conductive layer includes heating the conductive layer at a temperature ranging from 300° C. to 450° C. in operation S2750.

Embodiments of the present disclosure achieve lower bulk resistance than metal layers formed by a Cu damascene process. Lower resistance means less energy is lost as heat when electricity flows through the wire, resulting in more efficient operation. A thermal annealing operation in an ambient including Ar, N₂, H₂, H radical, or forming gas can cause the metal atoms in the metal layer to rearrange themselves into a more ordered configuration, that is, grain growth occurs. In some embodiments, the enlarged average grain sizes are greater than the average grain size of copper metal layers formed by a damascene process. This can reduce the scattering of electrons in a metal layer or wire, which in turn reduces its resistance.

The resistance is further reduced in some embodiments of the disclosure because the novel thermal annealing operation enables the use of metals like ruthenium instead of copper for wiring layers. Because copper is not used in some wiring layers, a barrier layer is not needed to prevent diffusion of copper. Thus, lower resistance barrier-less contacts can be made between wiring layers and contacts. In addition, the use of air gaps between conductive lines or wirings provides lower capacitance between the conductive lines or wirings.

Embodiments of the disclosure provide greater than 40% average grain size enlargement and greater than 27% or greater decrease in electrical resistance of the metal layer. In some embodiments, the average grain size enlargement is greater than 100% and the electrical resistance decrease is greater than 40%.

In some embodiments, the thermal annealing is performed at temperatures less than about 450° C., which prevents damage to underlying integrated circuit or semiconductor device components. Embodiments of the present disclosure have no yield or reliability degradation.

It will be understood that not all advantages have been necessarily discussed herein, no particular advantage is required for all embodiments or examples, and other embodiments or examples may offer different advantages.

An embodiment of the disclosure includes forming at least one semiconductor component in a semiconductor device component region over a substrate. An interconnect structure including at least one contact disposed in an insulating layer is formed over the semiconductor device component region. A conductive layer is formed over the interconnect structure. The conductive layer is annealed. The annealed conductive layer is etched to form a trench in the conductive layer. A remaining portion of the conductive layer overlaps the contact in the interconnect structure. A dielectric layer is formed in the trench. In an embodiment, the dielectric layer includes an air gap. In an embodiment, the dielectric layer further comprises an oxide layer formed over the air gap. In an embodiment, the etching the annealed conductive layer forms a plurality of trenches. In an embodiment, the method includes forming a trench liner layer on sidewalls of the trench before forming the dielectric layer. In an embodiment, the trench liner is made of an oxide doped carbide. In an embodiment, the annealing is performed at a temperature ranging from 300° C. to 450° C. In an embodiment, the annealing is performed in an ambient including at least one of Ar, N₂, H₂, or H radicals. In an embodiment, the conductive layer is made of Ru. In an embodiment, the etching is a reactive ion etching.

Another embodiment of the disclosure is a method of manufacturing a semiconductor device including forming at least one transistor in a semiconductor device component region over a substrate and forming an interconnect structure including an insulating layer over the semiconductor device component region. At least one conductive contact is formed in the insulating layer. A metal layer is deposited over the insulating layer. An average grain size of the metal layer increased. After increasing the average grain size of the metal layer, a trench is formed in the metal layer. At least one remaining portion of the metal layer overlaps the at least one conductive contact in the insulating layer. A dielectric layer is formed in the trench. The dielectric layer includes a second dielectric layer over a first dielectric layer and the first and second dielectric layers have a different dielectric constant k. In an embodiment, the first dielectric layer comprises an air gap. In an embodiment, the air gap is formed by depositing a polymer layer in the trench, depositing a sustain layer over the polymer layer, and removing the polymer layer after depositing the sustain layer. In an embodiment, the polymer layer is removed by a thermal oxidation operation. In an embodiment, the dielectric layer includes an oxide layer formed over the sustain layer. In an embodiment, the method includes forming a trench liner layer on sidewalls of the trench before forming the dielectric layer. In an embodiment, the trench liner is made of an oxide doped carbide.

Another embodiment of the disclosure is a method of manufacturing a semiconductor device, including forming a conductive layer over a substrate including at least one transistor and a conductive contact connected to the at least one transistor disposed in an insulating layer. The at least one transistor includes a gate structure including a gate electrode and a gate dielectric layer having a first dielectric constant k1. An average grain size of the conductive layer is increased. After increasing the average grain size of the conductive layer, the conductive layer is patterned to form an opening exposing the insulating layer. At least one remaining portion of the conductive layer overlaps a conductive contact in the insulating layer. A first dielectric liner layer is formed in the opening. A sacrificial layer is deposited over the dielectric liner layer. A second dielectric layer is deposited in the opening. The sacrificial layer is removed to form a gap having a second dielectric constant k2. A dielectric material having a third dielectric constant k3 is deposited in the opening, The third dielectric material is made of a different material than the second dielectric layer, k2 and k3 are different, k1>k2, and k1>k3. In an embodiment, the sacrificial layer is made of an organic polymer, and the removing the sacrificial layer includes heating the sacrificial layer at a temperature ranging from 200° C. to 400° C. In an embodiment, the increasing the average grain size of the conductive layer includes heating the conductive layer at a temperature ranging from 300° C. to 450° C. performed in an ambient including at least one of Ar, N₂, H₂, or H radicals.

Another embodiment of the disclosure is a structure, including a semiconductor device disposed on a substrate. An interconnect structure including at least one contact is disposed in an insulating layer over the semiconductor device. A conductive layer including a first conductive material is disposed over the interconnect structure. The conductive layer includes a plurality of metal structures spaced apart by a non-metal region, and the metal structures include a first metal having a first average grain size. A first liner layer is disposed in the non-metal region on sidewalls of the metal structures. A dielectric layer is disposed in the non-metal region over the first liner layer. The dielectric layer and the liner layer are made of different materials. An interlayer dielectric layer is disposed over the conductive layer. The interlayer dielectric layer includes at least one wiring layer embedded in the interlayer dielectric layer and a second liner layer is disposed between the wiring layer and the interlayer dielectric layer. The second liner layer includes the first metal having a second average grain smaller than the first average grain size. In an embodiment, the first metal includes ruthenium. In an embodiment, the dielectric layer includes an air gap. In an embodiment, the dielectric layer includes an oxide layer formed over the air gap. In an embodiment, the dielectric layer includes an oxide layer formed over the air gap. In an embodiment, at least one of the metal structures has a thickness of one grain of the first metal. In an embodiment, the liner layer is made of an oxide doped carbide. In an embodiment, the structure includes a contact connecting the semiconductor device and the conductive layer. In an embodiment, the contact includes a second conductive material, wherein the first conductive material and the second conductive material are different. In an embodiment, a second conductive layer is disposed between the first conductive layer and the contact, wherein the second conductive layer is made of a third conductive material, and the first conductive material, second conductive material, and third conductive material are different.

Another embodiment of the disclosure is a semiconductor device, including at least one semiconductor device disposed over a substrate, an interconnect structure disposed over the at least one semiconductor device. A metal layer is disposed over the interconnect structure. The metal layer includes a first metal having a first average grain thickness. At least two spaced-apart trenches are disposed in the metal layer, wherein the trenches penetrate through the metal layer. A portion of the metal layer between the two spaced-apart trenches overlaps a contact of the interconnect structure. A dielectric layer is disposed in the trenches including: a first dielectric layer having a first dielectric constant k1, and a second dielectric layer having a second dielectric constant k2 disposed over the first dielectric layer, wherein k1 and k2 are different. At least one wiring layer is disposed over the metal layer and electrically connected to the metal layer. A liner layer having a second average grain thickness surrounds the at least one wiring layer, wherein the first average grain thickness is greater than the second average grain thickness. In an embodiment, the at least one semiconductor device is connected to the metal layer through the contact of the interconnect structure. In an embodiment, the at least one semiconductor device includes at least one selected from the group consisting of a resistor, a capacitor, a diode, and a transistor. In an embodiment, the semiconductor device includes a trench liner layer between a trench sidewall and the dielectric layer, wherein the trench liner layer is made of a different material than the dielectric layer. In an embodiment, the trench liner is made of an oxide doped carbide.

Another embodiment of the disclosure is a semiconductor device including an insulating layer including at least one contact via disposed over a substrate including at least one transistor connected to the at least one contact via. The at least one transistor includes a gate structure including a gate electrode and a gate dielectric layer having a first dielectric constant. A conductive layer having at least one opening is disposed over the insulating layer. The conductive layer has a thickness of one grain of a conductive material. At least one portion of the conductive layer overlaps the at least one contact via in the insulating layer. A first liner layer is in the at least one opening. A first dielectric layer is in the at least one opening having a second dielectric constant k2, and a second dielectric layer having a third dielectric constant k3 is disposed over the first dielectric layer in the at least one opening, wherein k2 and k3 are different, k1>k2, and k1>k3. In an embodiment, the first dielectric layer includes an air gap. In an embodiment, the second dielectric layer includes an oxide layer. In an embodiment, the semiconductor device includes a wiring layer disposed over and electrically connected to the conductive layer. In an embodiment, the conductive material includes ruthenium.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming at least one semiconductor component in a semiconductor device component region over a substrate;
forming an interconnect structure comprising at least one contact disposed in an insulating layer over the semiconductor device component region;
forming a conductive layer over the interconnect structure;
annealing the conductive layer;
etching the annealed conductive layer to form a trench in the conductive layer,
wherein a remaining portion of the conductive layer overlaps the contact in the interconnect structure; and
forming a dielectric layer in the trench.

2. The method according to claim 1, wherein the dielectric layer comprises an air gap.

3. The method according to claim 2, wherein the dielectric layer further comprises an oxide layer formed over the air gap.
The method according to claim 1, wherein the etching the annealed conductive layer forms a plurality of trenches.

5. The method according to claim 1, further comprising forming a trench liner layer on sidewalls of the trench before forming the dielectric layer.

6. The method according to claim 5, wherein the trench liner is made of an oxide doped carbide.

7. The method according to claim 1, wherein the annealing is performed at a temperature ranging from 300° C. to 450° C.

8. The method according to claim 1, wherein the annealing is performed in an ambient including at least one of Ar, N₂, H₂, or H radicals.

9. The method according to claim 1, wherein the conductive layer is made of Ru.

10. The method according to claim 1, the etching is a reactive ion etching.

11. A method of manufacturing a semiconductor device, comprising:
forming at least one transistor in a semiconductor device component region over a substrate;
forming an interconnect structure including an insulating layer over the semiconductor device component region;
forming at least one conductive contact in the insulating layer;
depositing a metal layer over the insulating layer;
increasing an average grain size of the metal layer;
after increasing the average grain size of the metal layer, forming a trench in the metal layer,
wherein at least one remaining portion of the metal layer overlaps the at least one conductive contact in the insulating layer; and
forming a dielectric layer in the trench,
wherein the dielectric layer includes a second dielectric layer over a first dielectric layer and the first and second dielectric layers have a different dielectric constant.

12. The method according to claim 11, wherein the first dielectric layer comprises an air gap.

13. The method according to claim 12, wherein the air gap is formed by:
depositing a polymer layer in the trench;
depositing a sustain layer over the polymer layer: and removing the polymer layer after depositing the sustain layer.

14. The method according to claim 13, wherein the polymer layer is removed by a thermal oxidation operation.

15. The method according to claim 13, wherein the dielectric layer further comprises an oxide layer formed over the sustain layer.

16. The method according to claim 11, further comprising forming a trench liner layer on sidewalls of the trench before forming the dielectric layer.

17. The method according to claim 16, wherein the trench liner is made of an oxide doped carbide.

18. A structure, comprising:
a semiconductor device disposed on a substrate;
an interconnect structure comprising at least one contact disposed in an insulating layer over the semiconductor device;
a conductive layer disposed over the interconnect structure,
wherein the conductive layer comprises a plurality of metal structures spaced apart by a non-metal region, and
the metal structures comprise a first metal having a first average grain size;
a first liner layer disposed in the non-metal region on sidewalls of the metal structures;
a dielectric layer disposed in the non-metal region over the first liner layer,
wherein the dielectric layer and the liner layer are made of different materials; and
an interlayer dielectric layer disposed over the conductive layer,
wherein the interlayer dielectric layer includes at least one wiring layer embedded in the interlayer dielectric layer, and
a second liner layer disposed between the wiring layer and the interlayer dielectric layer,
the second liner layer comprising the first metal having a second average grain smaller than the first average grain size.

19. The structure of claim 18, wherein the first metal comprises ruthenium.

20. The structure of claim 18, wherein the dielectric layer comprises an air gap.
